(19) United States
(12) Patent Application Publication
(10) Pub. No.: US 2023/0274062 A1
(43) Pub. Date: Aug. 31, 2023

(54) SIGNAL DETECTION METHOD AND APPARATUS

(71) Applicant: Changxin Memory Technologies, Inc, Hefei City (CN)

(72) Inventor: Yuan CHEN, Hefei City (CN)

(21) Appl. No.: 17/804,690

(22) Filed: May 31, 2022

(30) Foreign Application Priority Data
Feb. 25, 2022 (CN) 202210181216.7

(51) Int. Cl. G06F 30/367

(52) U.S. Cl. CPC G06F 30/367

(57) ABSTRACT

Embodiments of the present disclosure provide a signal detection method and apparatus. The signal detection apparatus defines information of a correct output waveform of a to-be-detected signal in an excitation file, simulates a to-be-detected chip by using a specified emulator, to generate a simulation file including information of a simulated waveform of the to-be-detected signal, filters out noise in the simulated waveform to obtain a to-be-compared file, and compares the to-be-compared file with the excitation file to generate a detection result file; or compares the correct output waveform with the simulated waveform to obtain a candidate detection result, and filters out a result of a noise point in the candidate detection result to generate a detection result file.

### CROSS-REFERENCE TO RELATED APPLICATION

This application claims the priority of Chinese Patent Application No. 202210181216.7, submitted to the Chinese Intellectual Property Office on Feb. 25, 2022, the disclosure of which is incorporated herein in its entirety by reference.

### TECHNICAL FIELD

Embodiments of the present disclosure relate to the technical field of semiconductors, and in particular, to a signal detection method and apparatus.

### BACKGROUND

In a process of developing, designing, and commissioning a memory, simulation-based verification needs to be performed on a function of the memory by using simulation software. The memory is, for example, a dynamic random access memory (DRAM), and the simulation software is, for example, Finesim. As a high-performance accelerated simulation program with integrated circuit emphasis (SPICE), Finesim has been widely used for its speed and accuracy.

In the simulation-based verification of the memory, a large quantity of signals need to be verified through simulation, which will generate thousands of waveform result files. At present, these simulation results are mainly checked manually, resulting in low check efficiency and low check accuracy.

### SUMMARY

In some embodiments, a first aspect of the present disclosure provides a signal detection method, including:

obtaining an excitation file, where the excitation file includes information of a correct output waveform of a to-be-detected signal;

simulating a to-be-detected chip by using a specified emulator, to generate a simulation file, where the simulation file includes information of a simulated waveform of the to-be-detected signal;

filtering out noise in the simulated waveform to obtain a to-be-compared file, where the to-be-compared file includes information of a valid simulated waveform of the to-be-detected signal; and

comparing the to-be-compared file with the excitation file to generate a detection result file.

In some embodiments, a second aspect of the present disclosure provides a signal detection method, including:

obtaining an excitation file, where the excitation file includes information of a correct output waveform of a to-be-detected signal;

simulating a to-be-detected chip by using a specified emulator, to generate a simulation file, where the simulation file includes information of a simulated waveform of the to-be-detected signal;

comparing the correct output waveform with the simulated waveform to obtain a candidate detection result; and

filtering out a result of a noise point in the candidate detection result to generate a detection result file.

In some embodiments, a third aspect of the present disclosure provides a signal detection apparatus, including:

one or more processors; and

a storage apparatus, configured to store one or more programs, wherein the one or more programs, when executed by the one or more processors, cause the one or more processors to execute operations of:

obtaining an excitation file, where the excitation file includes information of a correct output waveform of a to-be-detected signal;

simulating a to-be-detected chip by using a specified emulator, to generate a simulation file, where the simulation file includes information of a simulated waveform of the to-be-detected signal;

filtering out noise in the simulated waveform to obtain a to-be-compared file, where the to-be-compared file includes information of a valid simulated waveform of the to-be-detected signal; and

comparing the to-be-compared file with the excitation file to generate a detection result file.

In some embodiments, a fourth aspect of the present disclosure provides a signal detection apparatus, including:

one or more processors; and

a storage apparatus, configured to store one or more programs, wherein the one or more programs, when executed by the one or more processors, cause the one or more processors to execute operations of:

obtaining an excitation file, where the excitation file includes information of a correct output waveform of a to-be-detected signal;

simulating a to-be-detected chip by using a specified emulator, to generate a simulation file, where the simulation file includes a simulated waveform of the to-be-detected signal;

comparing the correct output waveform with the simulated waveform to obtain a candidate detection result; and

filtering out a result of a noise point in the candidate detection result to generate a detection result file.

### BRIEF DESCRIPTIONS OF THE DRAWINGS

The accompanying drawings incorporated into the specification and constituting part of the specification illustrate the embodiments of the present disclosure, and serve, together with the specification, to explain the principles of the present disclosure.

FIG. 1 is a flowchart of a signal detection method according to Embodiment 1 of the present disclosure;

FIG. 2 is a flowchart of a signal detection method according to Embodiment 2 of the present disclosure;

FIG. 3 is a schematic diagram of a simulated waveform and a voltage reference line of a DQS;

FIG. 4 is a flowchart of a signal detection method according to Embodiment 3 of the present disclosure;

FIG. 5 is a flowchart of a signal detection method according to Embodiment 4 of the present disclosure;

FIG. 6 is a schematic diagram of a clock signal of a chip;

FIG. 7 is a schematic structural diagram of a signal detection apparatus according to Embodiment 5 of the present disclosure;

FIG. 8 is a schematic structural diagram of a signal detection apparatus according to Embodiment 6 of the present disclosure; and

FIG. 9 is a schematic structural diagram of a signal detection apparatus according to Embodiment 7 of the present disclosure.

Specific embodiments of the present application are shown by using the accompanying drawings and are described below in more detail. The accompanying drawings and text description are not intended to limit the scope of the concept of the present application in any manner, but to explain the concept of the present application for those skilled in the art with reference to specific embodiments.

### DETAILED DESCRIPTION

Exemplary embodiments are described in detail herein, and examples thereof are represented in the accompanying drawings. When the following descriptions relate to the accompanying drawings, unless otherwise stated, same digitals in different accompanying drawings represent same or similar essential factors. Implementations described in the following exemplary embodiments do not represent all implementations consistent with the present disclosure. On the contrary, the implementations are merely examples of apparatuses and methods that are described in detail in the appended claims and consistent with some aspects of the present disclosure.

The embodiments of the present disclosure provide a signal detection method, which can detect a result obtained by a specified emulator through simulation, to automatically determine whether the simulation result is correct. The specified emulator is configured to simulate a to-be-detected chip to generate a simulation file, where the simulation file includes information of a simulated waveform of a to-be-detected signal. The specified emulator may be Finesim. Finesim has advantages of a fast speed and high accuracy in simulation-based verification of a DRAM, but does not provide a corresponding mechanism or language for a generated waveform result file to determine whether a result is correct. Instead, the result can only be checked manually. In the manual check, some check items are missing or incorrectly checked, and a check speed is slow.

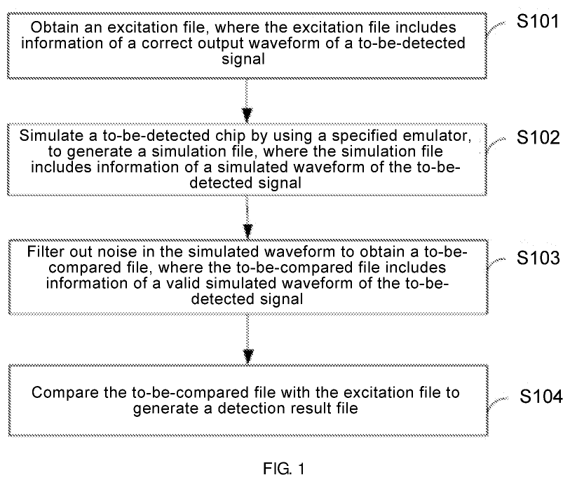

FIG. 1 is a flowchart of a signal detection method according to Embodiment 1 of the present disclosure. The signal detection method in this embodiment may be executed by a signal detection apparatus. The signal detection apparatus may be integrated in an emulator or may be an independent device. The signal detection apparatus is configured to detect a simulation result of a to-be-detected chip. The to-be-detected chip includes but is not limited to a DRAM. This embodiment provides description by using an example in which the to-be-detected chip is the DRAM. As shown in FIG. 1, the signal detection method in this embodiment includes the following steps.

S101: Obtain an excitation file, where the excitation file includes information of a correct output waveform of a to-be-detected signal.

The excitation file can be obtained by using a model developed by verification personnel. The excitation file defines the information of the correct output waveform of the to-be-detected signal. The information of the correct output waveform of the to-be-detected signal includes a voltage value or a logic voltage value that the to-be-detected signal should have at each time point. The voltage value is an analog quantity, such as 0.746 V or 0.5 V. The logic voltage value is a digital quantity, which can be expressed in a form of 0/1, where 0 indicates a low level and 1 indicates a high level. The voltage value and the logic voltage value can be converted. For example, when the voltage value is 0.746 V, if a reference voltage is 0.7 V, the corresponding logic voltage value is 1.

The to-be-detected signal includes but is not limited to a DQ. The DQ is used to write data into the DRAM and read data from the DRAM. A DQS is used for signal synchronization between a memory controller and a memory (namely, the DRAM). When the memory controller writes data into the DRAM (in other words, performs a write operation), the memory controller generates a DQS. A rising or falling edge (which can be collectively referred to as an edge) of the DQS is aligned with an edge of the DQ. The DRAM determines, based on the edge of the DQS, time of receiving the written data. When the memory controller reads data from the DRAM (in other words, performs a read operation), the DRAM generates a DQS, and an edge of the DQS is aligned with the edge of the DQ. The memory controller determines, based on the edge of the DQS, time of receiving the read data.

S102: Simulate the to-be-detected chip by using a specified emulator, to generate a simulation file, where the simulation file includes information of a simulated waveform of the to-be-detected signal.

For example, the specified emulator is Finesim. Finesim measures the information of the simulated waveform, such that design personnel can compile a corresponding measure file based on the to-be-detected signal, and add the measure file when using Finesim to perform simulation. Accordingly, after the measure file is executed, a measurement result file is automatically generated.

The information of the simulated waveform of the to-be-detected signal corresponds to the information of the correct output waveform of the to-be-detected signal. When the information of the correct output waveform of the to-be-detected signal is the voltage value that the to-be-detected signal should have at each time point, the information of the simulated waveform of the to-be-detected signal is a measured voltage value of the simulated waveform of the to-be-detected signal at each time point. When the to-be-detected signal is the DQ, the simulated waveform includes a simulated waveform of the DQ and a simulated waveform of the DQS.

S103: Filter out noise in the simulated waveform to obtain a to-be-compared file, where the to-be-compared file includes information of a valid simulated waveform of the to-be-detected signal.

Some noise exists in the simulated waveform, and may result in a wrong detection result and reduce correctness of a detection result of the to-be-detected signal. Therefore, the noise needs to be eliminated. In this embodiment, the noise refers to all factors that may cause an error to the detection result.

It can be understood that types of noise in simulated waveforms of different to-be-detected signals may be different. Taking the DQ as an example, the noise in the simulated waveform includes an invalid change point of the DQS. A change point of the DQS is a time point corresponding to the rising or falling edge of the DQS, or a time point when the DQS changes from the high level to the low level, and a time point when the DQS changes from the low level to the high level. The rising edge is a wave band in which a level of a waveform changes from the low level to the high level, and the falling edge is a wave band in which the level of the waveform changes from the high level to the low level.

The invalid change point of the DQS includes one or more of the following change points: a change point of the DQS in a first time period, where in the first time period, the DQS is in a state of not strobing the DQ; and a point of intersection between a first change of a signal edge of the DQS and a voltage reference line in a second time period, where in the second time period, the DQS is in a state of strobing the DQ.

S104: Compare the to-be-compared file with the excitation file to generate a detection result file.

The excitation file defines the information of the correct output waveform of the to-be-detected signal, and the to-be-compared file includes the information of the valid simulated waveform of the to-be-detected signal. The information of the correct output waveform is compared with the information of the valid simulated waveform to obtain the detection result. For example, a correct logic voltage value of the DQ at each time point is compared with a simulated logic voltage value of the DQ at each time point to determine whether a logic voltage value of the simulated waveform of the DQ at each time point is correct.

Optionally, the detection result file can be displayed to a user through a display screen, such that the user can intuitively understand the detection result of the signal. Further, a wrong point of the signal can be displayed to the user in a form of a waveform or a table, or whether a simulation result is correct can be expressed in a form of a matrix.

In some embodiments, the signal detection apparatus defines the information of the correct output waveform of the to-be-detected signal in the excitation file, simulates the to-be-detected chip by using the specified emulator, to generate the simulation file including the information of the simulated waveform of the to-be-detected signal, filters out the noise in the simulated waveform to obtain the to-be-compared file including the information of the valid simulated waveform of the to-be-detected signal, and compares the to-be-compared file with the excitation file to generate the detection result file. In this manner, the information of the correct output waveform and the valid simulated waveform of the to-be-detected signal is automatically compared, so as to automatically detect whether the simulation result of the signal is correct, thereby improving efficiency of signal detection.

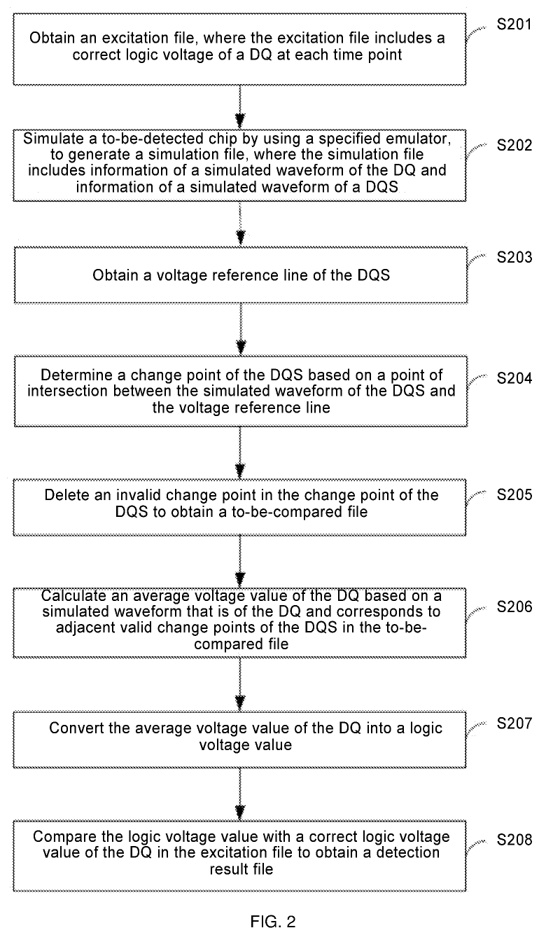

Based on Embodiment 1, Embodiment 2 of the present disclosure illustrates a DQ detection method by using an example in which the to-be-detected signal is the DQ. In verification of a memory design, a basic condition for determining correctness of the memory design is that the DQ is correct. FIG. 2 is a flowchart of a signal detection method according to Embodiment 2 of the present disclosure. As shown in FIG. 2, the signal detection method provided in this embodiment includes the following steps.

S201: Obtain an excitation file, where the excitation file includes a correct logic voltage of a DQ at each time point.

S202: Simulate a to-be-detected chip by using a specified emulator, to generate a simulation file, where the simulation file includes information of a simulated waveform of the DQ and information of a simulated waveform of a DQS.

S203: Obtain a voltage reference line of the DQS.

The voltage reference line is a straight line in a same dimension as the simulated waveform of the DQS, and a voltage value corresponding to the voltage reference line is between a maximum voltage value and a minimum voltage value of the DQS.

For example, half of a sum of the maximum voltage value and the minimum voltage value of the DQS is determined as a voltage reference value, and the voltage reference line is generated based on the voltage reference value and the simulated waveform of the DQS. The voltage reference line is a straight line that is in the same dimension as the simulated waveform of the DQS and whose corresponding voltage value is equal to the voltage reference value. Herein, an example in which the voltage reference value is half of the sum of the maximum voltage value and the minimum voltage value of the DQS is used. It can be understood that the voltage reference value can also increase or decrease based on half of the sum of the maximum voltage value and the minimum voltage value of the DQS.

S204: Determine a change point of the DQS based on a point of intersection between the simulated waveform of the DQS and the voltage reference line.

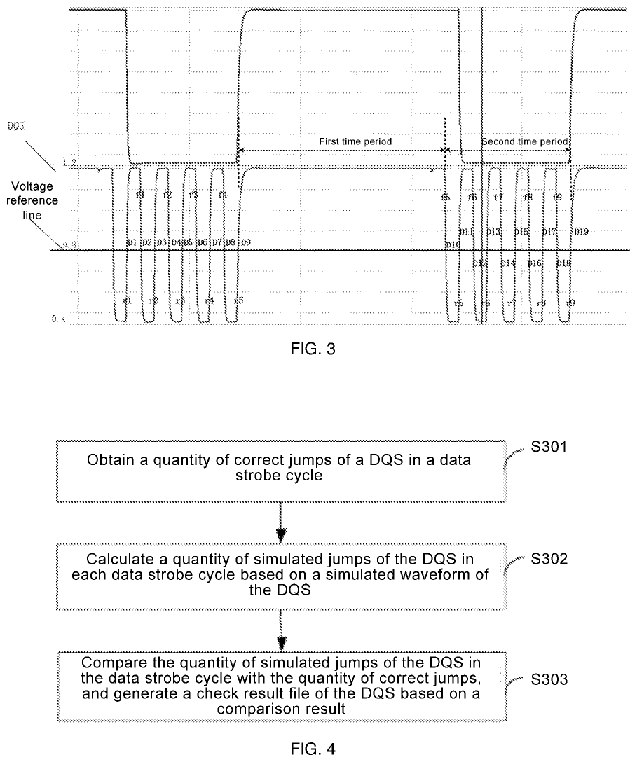

FIG. 3 is a schematic diagram of the simulated waveform and the voltage reference line of the DQS. As shown in FIG. 3, the maximum voltage value of the DQS is 1.2 V and the minimum voltage value of the DQS is 0.4 V. A dotted line in the figure represents the voltage reference line, and the voltage reference value is 0.8 V, which is half of the maximum voltage value and minimum voltage value of the DQS.

The change point of the DQS is the point of intersection between the simulated waveform of the DQS and the voltage reference line. As shown in the figure, there are a total of 10 points of intersection between the simulated waveform and the voltage reference line of the DQS (namely, change points of the DQS) in a cycle (namely, a first time period+a second time period), which are respectively denoted as D10, . . . , and D19. The points of intersection each are generated by rising and falling edges of the DQS. Each change point of the DQS corresponds to a voltage value change of the DQS. In the figure, r1 to r9 represent rising edges, and f1 to f9 represents falling edges.

S205: Delete an invalid change point in the change point of the DQS to obtain a to-be-compared file.

The invalid change point of the DQS includes one or more of the following change points: a change point of the DQS in the first time period, where in the first time period, the DQS is in a state of not strobing the DQ; and a point of intersection between a first change of a signal edge of the DQS and a voltage reference line in the second time period, where in the second time period, the DQS is in a state of strobing the DQ.

Taking FIG. 3 as an example, the first time period may be a time period between D9 and D10, excluding D9 and D10. In this time period, the DQS does not strobe the DQ, that is, each change point with a signal jump in this time period is considered as the invalid change point. The second time period is a time period between D10 and D19, including D10 and D19. In this time period, the DQS is in the state of strobing the DQ. In a strobing process, the point of intersection (D10) between the first change of the signal edge of the DQS and the voltage reference line is the invalid change point because data of the DQ is not strobed in the first change of the signal edge of the DQS.

Noise in the simulated waveform of the DQS is filtered out by performing steps S203 to S205.

S206: Calculate an average voltage value of the DQ based on a simulated waveform that is of the DQ and corresponds to adjacent valid change points of the DQS in the to-be-compared file.

Taking FIG. 3 as an example, D11 to D19 are valid change points of the DQS. Therefore, simulated waveforms that are of the DQ and correspond to eight time periods D11 to D12, D12 to D13, . . . , D17 to D18, and D18 to D19 respectively are determined. An average voltage value of the DQ in each time period is calculated based on a voltage value of a simulated waveform that is of the DQ and corresponds to the time period, and the average voltage values of the DQ in the eight time periods are obtained.

S207: Convert the average voltage value of the DQ into a logic voltage value.

The calculated average voltage value of the DQ in each time period in step S206 is an analog voltage, which is converted into the logic voltage value based on the average voltage value of the DQ and a reference voltage.

S208: Compare the logic voltage value with a correct logic voltage value of the DQ in the excitation file to obtain a detection result file.

The calculated logic voltage value of the DQ in each time period is compared with the correct logic voltage value that is of the DQ and set in the same time period in the excitation file. When a calculated logic voltage value of the DQ in a time period is the same as a correct logic voltage value in the time period, it is determined that a DQ obtained through simulation in the time period is correct. When a calculated logic voltage value of the DQ in a time period is different from a correct logic voltage value in the time period, it is determined that a DQ obtained through simulation in the time period is wrong.

In this embodiment, after the simulated waveform of the DQ and the simulated waveform of the DQS are obtained, the change point of the DQS is determined and the invalid change point of the DQS is deleted, the average voltage value of the DQ is calculated based on the simulated waveform that is of the DQ and corresponds to the adjacent valid change points of the DQS, the average voltage value of the DQ is converted into the logic voltage value, and the logic voltage value is compared with the correct logic voltage value of the DQ in the excitation file to obtain the detection result file. This can automatically detect whether a simulation result of the DQ is correct, and eliminate an invalid DQS, making a detection result more accurate.

Based on Embodiment 2, in a possible embodiment, correctness of the simulated waveform of the DQS is checked before the invalid change point in the change point of the DQS is deleted. Embodiment 3 of the present disclosure describes in detail a method for checking the correctness of the simulated waveform of the DQS. FIG. 4 is a flowchart of a signal detection method according to Embodiment 3 of the present disclosure. As shown in FIG. 4, the signal detection method provided in this embodiment includes the following steps.

S301: Obtain a quantity of correct jumps of a DQS in a data strobe cycle.

A jump of the DQS means that a voltage of DQS changes from a high level to a low level or from a low level to a high level. A quantity of jumps of the DQS in a data gating cycle includes a sum of a quantity of voltage changes of the DQS from the high level to the low level and a quantity of voltage changes of the DQS from the low level to the high level in the data gating cycle. Each jump corresponds to a rising or falling edge of the DQS. Therefore, a quantity of correct jumps of the DQS in a data strobe cycle can also be a sum of a quantity of rising edges of the DQS and a quantity of falling edges of the DQS in the data strobe cycle.

The quantity of correct jumps may be included in an excitation file, and a signal detection apparatus can read the quantity of correct jumps from the excitation file.

S302: Calculate a quantity of simulated jumps of the DQS in each data strobe cycle based on a simulated waveform of the DQS.

The simulated waveform of the DQS can reflect a voltage change of the DQS. The quantity of simulated jumps of the DQS can be obtained based on a change of a voltage amplitude of the simulated waveform of the DQS. Taking the DQS shown in FIG. 3 as an example, a quantity of jumps of the DQS in a data strobe cycle is 10.

S303: Compare the quantity of simulated jumps of the DQS in the data strobe cycle with the quantity of correct jumps, and generate a check result file of the DQS based on a comparison result.

When the quantity of simulated jumps of the DQS in the data strobe cycle is the same as the quantity of correct jumps, it is determined that the simulated waveform of the DQS in the data strobe cycle is normal. When the quantity of simulated jumps of the DQS in the data strobe cycle is different from the quantity of correct jumps, it is determined that the simulated waveform of the DQS in the data strobe cycle is abnormal.

Taking the DQS shown in FIG. 3 as an example, the quantity of correct jumps of the DQS in the data strobe cycle is 10. When the quantity of simulated jumps of the DQS in the data strobe cycle is less than or greater than 10, it is determined that the simulated waveform of the DQS in the data strobe cycle is abnormal. For example, when the quantity of simulated jumps of the DQS in the data strobe cycle is 8 or 11, it is determined that the simulated waveform of the DQS in the data strobe cycle is abnormal.

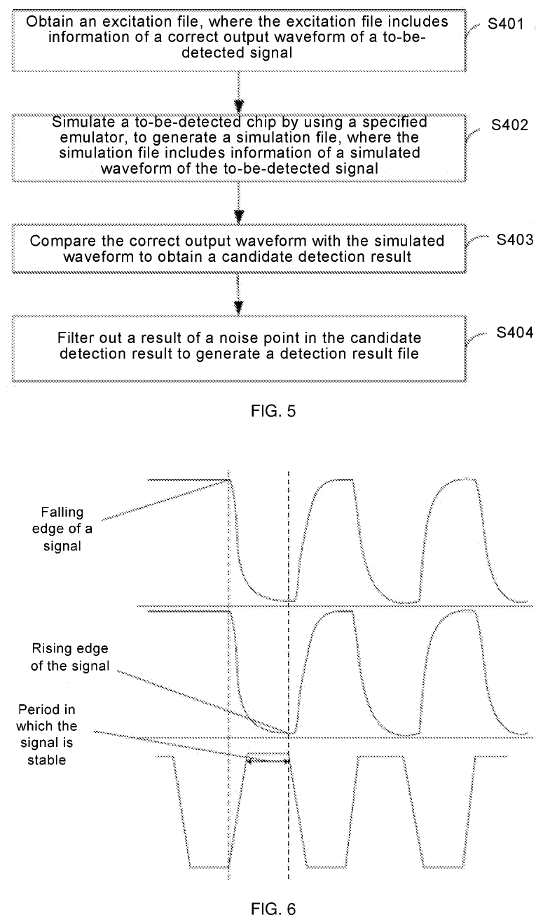

FIG. 5 is a flowchart of a signal detection method according to Embodiment 4 of the present disclosure. The signal detection method in this embodiment and the signal detection method in Embodiment 1 are used to detect different signals. As shown in FIG. 5, the signal detection method in this embodiment includes the following steps.

S401: Obtain an excitation file, where the excitation file includes information of a correct output waveform of a to-be-detected signal.

S402: Simulate a to-be-detected chip by using a specified emulator, to generate a simulation file, where the simulation file includes information of a simulated waveform of the to-be-detected signal.

For specific implementations of S401 and S402, reference may be made to the related description of steps S101 and 102 in Embodiment 1. Specific principles are similar except that the to-be-detected signals are different. In this embodiment, the to-be-detected signal may be an external output signal of the to-be-detected chip.

S403: Compare the correct output waveform with the simulated waveform to obtain a candidate detection result.

For example, the correct output waveform and the simulated waveform are sampled under a same sampling condition, and voltage values of the correct output waveform and the simulated waveform at each sampling time point are compared to obtain the candidate detection result.

The same sampling condition includes but is not limited to a sampling frequency. The sampling frequency is N times a frequency of a clock signal of the chip, and N is greater than or equal to 2. If the sampling frequency is equal to the frequency of the clock signal of the chip, when a sampling point is located at an edge of the correct output waveform or the simulated waveform, a sampled voltage value is likely to be wrong due to a jump of the signal, resulting in a wrong detection result. Therefore, the sampling frequency should be at least 2 times the frequency of the clock signal, so as to ensure that the sampled voltage values include a correct voltage value and improve accuracy of the detection result.

When the voltage values of the correct output waveform and the simulated waveform at each sampling time point are compared, when voltage values of the correct output waveform and the simulated waveform at each sampling time point in a half cycle of the clock signal of the chip are not the same, it is determined that an error occurs on the simulated waveform of the to-be-detected signal in the half cycle of the clock signal of the chip. When voltage values of the correct output waveform and the simulated waveform at one or more sampling time points in the half cycle of the clock signal of the chip are the same, it is determined that no error occurs on the simulated waveform of the to-be-detected signal in the half cycle of the clock signal of the chip.

The simulated waveform and the correct output waveform do not jump in the half cycle of the clock signal, that is, the voltage values of the simulated waveform and the correct output waveform do not jump from a high level to a low level, or jump from the low level to the high level. Therefore, the simulated waveform of the to-be-detected signal is correct in the half cycle of the clock signal of the chip, provided that a voltage value at one sampling time point is correct in the half cycle of the clock signal.

Similarly, when the error occurs on the simulated waveform, the whole simulated waveform is reversed in the half cycle of the clock signal, for example, the voltage value of the simulated waveform changes from the low level to the high level or from the high level to the low level in the half cycle of the clock signal. Accordingly, the voltage value collected at each sampling time point is reversed. Therefore, when the voltage values of the correct output waveform and the simulated waveform at each sampling time point in the half cycle of the clock signal of the chip are not the same, it is determined that the error occurs on the simulated waveform of the to-be-detected signal in the half cycle of the clock signal of the chip.

S404: Filter out a result of a noise point in the candidate detection result to generate a detection result file.

Some noise exists in the candidate detection result, and needs to be filtered out. In this embodiment, the noise refers to all factors that may cause an error to the detection result. An accurate detection result file can be obtained by filtering out the noise point.

For example, the candidate detection result includes detection results of the simulated waveform in a plurality of clock signals of the chip and a voltage value of each sampling point in each clock signal. A detection result of the simulated waveform in the half cycle of the clock signal of the chip is used to indicate whether the simulated waveform in the half cycle of the clock signal of the chip is correct. That the simulated waveform in the half cycle of the clock signal of the chip is correct may be represented by true, and that the simulated waveform in the half cycle of the clock signal of the chip is incorrect may be represented by false; or that the simulated waveform in the half cycle of the clock signal of the chip is correct may be represented by 1, and that the simulated waveform in the half cycle of the clock signal of the chip is incorrect may be represented by 0. Here is only an example.

Correspondingly, the determining a noise point from the candidate detection result is: when a logic voltage value of at least one sampling time point in the half cycle of the clock signal of the chip is the same, determining another target sampling time point with a different logic voltage value as the noise point; and filtering out a sampling result of the noise point to generate the detection result file. The detection result file includes detection results of the simulated waveform in half cycles of the plurality of clock signals of the chip and a voltage value of a correct sampling point in a half cycle of each clock signal of the chip.

In the half cycle of the clock signal of the chip, some sampling time points may be located at a jump edge of a clock signal cycle of the chip. For sampling time points at an edge of the clock signal, collected voltages may be wrong due to a signal jump at a clock edge. Therefore, voltage values of the simulated waveform that are collected at these sampling time points may be different from those of the correct output waveform that are collected at these sampling time points. Therefore, the sampling points usually located at the jump edge of the clock signal cycle of the chip are noise points, and need to be filtered out.

FIG. 6 is a schematic diagram of the clock signal of the chip. As shown in FIG. 6, it is not necessary to pay attention to whether voltage values of sampling point at rising and falling edges of the clock signal of the chip are correct, but it is only necessary to pay attention to whether a voltage value of a sampling point in a period in which the signal is stable is correct. Therefore, the sampling points at the rising and falling edges of the clock signal of the chip are noise points. It can be understood that the rising and falling edges of the clock signal of the chip and the period in which the clock signal of the chip is stable in FIG. 6 are only schematic. Switching time of the rising and falling edges of the signal may be different in different devices, and the switching time of the rising edge may be less than that of the falling edge. In some cases, the switching time of the rising edge or the falling edge may be 0 or very small, and can be ignored.

In this embodiment, a signal detection apparatus defines the information of the correct output waveform of the to-be-detected signal in the excitation file, simulates the to-be-detected chip by using the specified emulator, to generate the simulation file including the information of the simulated waveform of the to-be-detected signal, compares the correct output waveform with the simulated waveform to obtain the candidate detection result, and filters out the result of the noise point in the candidate detection result to generate the detection result file. In this manner, the information of the correct output waveform and the valid simulated waveform of the to-be-detected signal is automatically compared, so as to automatically detect whether the simulation result of the signal is correct, thereby improving efficiency of signal detection. Moreover, the result of the noise point in the candidate detection result is filtered out after the candidate detection result is obtained, thereby improving accuracy of the detection result.

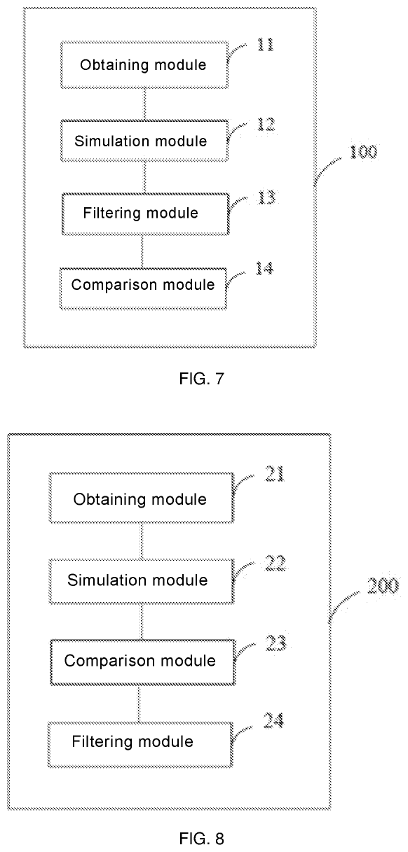

FIG. 7 is a schematic structural diagram of a signal detection apparatus according to Embodiment 5 of the present disclosure. As shown in FIG. 7, the signal detection apparatus 100 includes:

an obtaining module 11, configured to obtain an excitation file, where the excitation file includes information of a correct output waveform of a to-be-detected signal;

a simulation module 12, configured to simulate a to-be-detected chip by using a specified emulator, to generate a simulation file, where the simulation file includes a simulated waveform of the to-be-detected signal;

a filtering module 13, configured to filter out noise in the simulated waveform to obtain a to-be-compared file, where the to-be-compared file includes information of a valid simulated waveform of the to-be-detected signal; and

a comparison module 14, configured to compare the to-be-compared file with the excitation file to generate a detection result file.

In an embodiment, the simulated waveform includes a simulated waveform of a DQ and a simulated waveform of a DQS, and the filtering module 13 is specifically configured to:

obtain a voltage reference line of the DQS, where the voltage reference line is a straight line in a same dimension as the simulated waveform of the DQS, and a voltage value corresponding to the voltage reference line is between a maximum voltage value and a minimum voltage value of the DQS;

determine a change point of the DQS based on a point of intersection between the simulated waveform of the DQS and the voltage reference line; and

delete an invalid change point in the change point of the DQS to obtain the to-be-compared file.

In an embodiment, the obtaining a voltage reference line of the DQS is specifically:

determining half of a sum of the maximum voltage value and the minimum voltage value of the DQS as a voltage reference value; and

generating the voltage reference line based on the voltage reference value and the simulated waveform of the DQS, where the voltage reference line is a straight line that is in the same dimension as the simulated waveform of the DQS and whose corresponding voltage value is equal to the voltage reference value.

In an embodiment, the invalid change point includes one or more of the following change points: a change point of the DQS in a first time period, where in the first time period, the DQS is in a state of not strobing the DQ; and a point of intersection between a first change of a signal edge of the DQS and the voltage reference line in a second time period, where in the second time period, the DQS is in a state of strobing the DQ.

In an embodiment, the comparison module 14 is specifically configured to: calculate an average voltage value of the DQ based on a simulated waveform that is of the DQ and corresponds to adjacent valid change points of the DQS; convert the average voltage value of the DQ into a logic voltage value; and compare the logic voltage value with a correct logic voltage value of the DQ in the excitation file to obtain the detection result file.

In an embodiment, the signal detection apparatus further includes a check module, configured to check correctness of the simulated waveform of the DQS.

In an embodiment, the check module is specifically configured to: obtain a quantity of correct jumps of the DQS in a data strobe cycle; calculate a quantity of simulated jumps of the DQS in each data strobe cycle based on the simulated waveform of the DQS; and compare the quantity of simulated jumps of the DQS in the data strobe cycle with the quantity of correct jumps, and generate a check result file of the DQS based on a comparison result.

In an embodiment, the comparing the quantity of simulated jumps of the DQS in the data strobe cycle with the quantity of correct jumps is specifically: when the quantity of simulated jumps of the DQS in the data strobe cycle is the same as the quantity of correct jumps, determining that the simulated waveform of the DQS in the data strobe cycle is normal; or when the quantity of simulated jumps of the DQS in the data strobe cycle is different from the quantity of correct jumps, determining that the simulated waveform of the DQS in the data strobe cycle is abnormal.

The apparatus in this embodiment can be configured to execute the method described in any one of Embodiment 1 to Embodiment 3. Specific implementations and technical effects are similar, and details are not described herein again.

FIG. 8 is a schematic structural diagram of a signal detection apparatus according to Embodiment 6 of the present disclosure. As shown in FIG. 8, the signal detection apparatus 200 includes:

an obtaining module 21, configured to obtain an excitation file, where the excitation file includes information of a correct output waveform of a to-be-detected signal;

a simulation module 22, configured to simulate a to-be-detected chip by using a specified emulator, to generate a simulation file, where the simulation file includes a simulated waveform of the to-be-detected signal;

a comparison module 23, configured to compare the correct output waveform with the simulated waveform to obtain a candidate detection result; and

a filtering module 24, configured to filter out a result of a noise point in the candidate detection result to generate a detection result file.

In an embodiment, the comparison module 23 is specifically configured to: sample the correct output waveform and the simulated waveform under a same sampling condition, and compare voltage values of the correct output waveform and the simulated waveform at each sampling time point.

In an embodiment, the same sampling condition includes a sampling frequency, the sampling frequency is N times a frequency of a clock signal of the chip, and N is greater than or equal to 2.

In an embodiment, the comparing voltage values of the correct output waveform and the simulated waveform at each sampling time point is specifically: when voltage values of the correct output waveform and the simulated waveform at each sampling time point in a half cycle of the clock signal of the chip are not the same, determining that an error occurs on the simulated waveform of the to-be-detected signal in the half cycle of the clock signal of the chip; and when voltage values of the correct output waveform and the simulated waveform at one or more sampling time points in the half cycle of the clock signal of the chip are the same, determining that no error occurs on the simulated waveform of the to-be-detected signal in the half cycle of the clock signal of the chip.

In an embodiment, the filtering module 24 is specifically configured to: determine a target sampling time point with a different logic voltage value in the half cycle of the clock signal of the chip as the noise point; and filter out a sampling result of the noise point to generate the detection result file.

In an embodiment, the to-be-detected signal is an external output signal of the to-be-detected chip.

The apparatus in this embodiment can be configured to execute the method described in Embodiment 4. Specific implementations and technical effects are similar, and details are not described herein again.

It should be noted that when the apparatus provided in the foregoing embodiment executes the signal detection method, the division of the foregoing functional modules is merely an example for description. In practical application, the functions may be assigned to and completed by different functional modules as required. That is, an internal structure of the apparatus is divided into different functional modules, to complete all or some of the functions described above.

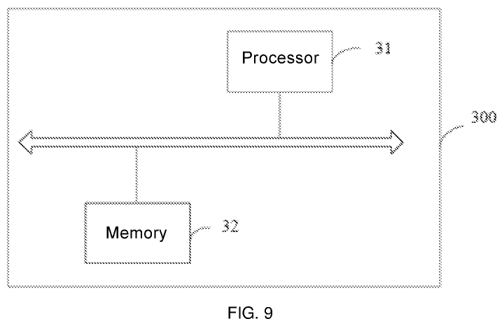

FIG. 9 is a schematic structural diagram of a signal detection apparatus according to Embodiment 7 of the present disclosure. As shown in FIG. 9, the signal detection apparatus 300 includes: at least one processor 31 and a memory 32, where the memory 32 stores computer executable instructions; and the at least one processor 31 executes the computer executable instructions stored in the memory 32, such that the at least one processor 31 performs the method according to any one of Embodiment 1 to Embodiment 4. Specific implementations and technical effects are similar, and details are not described herein again.

Persons skilled in the art should understand that the embodiments of the present disclosure may be provided as a method, an apparatus (device), or a computer program product. Therefore, the present disclosure may use a form of hardware only examples, software only examples, or examples with a combination of software and hardware. Moreover, the present disclosure may be in a form of a computer program product that is implemented on one or more computer-usable storage media that include computer-usable program code. The computer storage media include volatile and non-volatile, removable and non-removable media implemented in any method or technology for storing information (such as computer-readable instructions, data structures, program modules, or other data), including but not limited to, a RAM, a ROM, an EEPROM, a flash memory or other storage technologies, a CD-ROM, a digital versatile disk (DVD) or other optical disc storage, a magnetic cassette, a magnetic tape, magnetic disk storage or other magnetic storage apparatuses, or any other medium that can be used to store desired information and can be accessed by a computer. In addition, as is well known to persons of ordinary skill in the art, the communication media usually contain computer-readable instructions, data structures, program modules, or other data in modulated data signals such as carrier waves or other transmission mechanisms, and may include any information transfer medium.

The embodiments of the present disclosure further provide a computer program product including a computer program. The computer program is executed by a processor to implement the method described in any one of Embodiment 1 to Embodiment 4. Specific implementations and technical effects are similar, and details are not described herein again.

The embodiments of the present disclosure further provide a computer-readable storage medium. Referring to FIG. 9, for example, the computer-readable storage medium may be the memory 32 storing computer executable instructions. The computer executable instructions are executed by a processor 31 to implement the method described in any one of Embodiment 1 to Embodiment 4. Specific implementations and technical effects are similar, and details are not described herein again.

These computer executable instructions may also be stored in a computer readable memory that can instruct the computer or any other programmable data processing device to work in a specific manner, such that the instructions stored in the computer readable memory generate an artifact that includes an instruction apparatus. The instruction apparatus implements a specific function in one or more processes in the flowcharts and/or in one or more blocks in the block diagrams.

These computer executable instructions may also be loaded onto a computer or another programmable data processing device, such that a series of operations and steps are performed on the computer or the another programmable device, thereby generating computer-implemented processing. Therefore, the instructions executed on the computer or the another programmable device provide steps for implementing a function specified in one or more processes in the flowcharts and/or in one or more blocks in the block diagrams.

Those skilled in the art may easily figure out other implementation solutions of the present disclosure after considering the specification and practicing the application disclosed herein. The present disclosure is intended to cover any variations, purposes or applicable changes of the present disclosure. Such variations, purposes or applicable changes follow the general principle of the present disclosure and include common knowledge or conventional technical means in the technical field which is not disclosed in the present disclosure. The specification and embodiments are merely considered as illustrative, and the real scope and spirit of the present disclosure are pointed out by the appended claims.

It should be noted that the present disclosure is not limited to the precise structures described above and shown in the accompanying drawings, and can be modified and changed in many ways without departing from the scope of the present disclosure. The scope of the present disclosure is defined by the appended claims.

1. A signal detection method, comprising:
obtaining an excitation file, wherein the excitation file comprises information of a correct output waveform of a to-be-detected signal;
simulating a to-be-detected chip by using a specified emulator, to generate a simulation file, wherein the simulation file comprises information of a simulated waveform of the to-be-detected signal;
filtering out noise in the simulated waveform to obtain a to-be-compared file, wherein the to-be-compared file comprises information of a valid simulated waveform of the to-be-detected signal; and
comparing the to-be-compared file with the excitation file to generate a detection result file.

2. The signal detection method according to claim 1, wherein the simulated waveform comprises a simulated waveform of a data signal and a simulated waveform of a data strobe signal, and the filtering out noise in the simulated waveform to obtain a to-be-compared file comprises:
obtaining a voltage reference line of the data strobe signal, wherein the voltage reference line is a straight line in a same dimension as the simulated waveform of the data strobe signal, and a voltage value corresponding to the voltage reference line is between a maximum voltage value and a minimum voltage value of the data strobe signal;
determining a change point of the data strobe signal based on a point of intersection between the simulated waveform of the data strobe signal and the voltage reference line; and
deleting an invalid change point in the change point of the data strobe signal to obtain the to-be-compared file.

3. The signal detection method according to claim 2, wherein the obtaining a voltage reference line of the data strobe signal comprises:
determining half of a sum of the maximum voltage value and the minimum voltage value of the data strobe signal as a voltage reference value; and
generating the voltage reference line based on the voltage reference value and the simulated waveform of the data strobe signal, wherein the voltage reference line is a straight line that is in the same dimension as the simulated waveform of the data strobe signal and whose corresponding voltage value is equal to the voltage reference value.

4. The signal detection method according to claim 3, wherein the invalid change point comprises one or more of the following change points:
a change point of the data strobe signal in a first time period, wherein in the first time period, the data strobe signal is in a state of not strobing the data signal; and
a point of intersection between a first change of a signal edge of the data strobe signal and the voltage reference line in a second time period, wherein in the second time period, the data strobe signal is in a state of strobing the data signal.

5. The signal detection method according to claim 4, wherein the information of the correct output waveform of the to-be-detected signal is a correct logic voltage value of the data signal at each time point, and the comparing the to-be-compared file with the excitation file to generate a detection result file comprises:
calculating an average voltage value of the data signal based on a simulated waveform that is of the data signal and corresponds to adjacent valid change points of the data strobe signal;
converting the average voltage value of the data signal into a logic voltage value; and
comparing the logic voltage value with the correct logic voltage value of the data signal in the excitation file, and obtaining the detection result file.

6. The signal detection method according to claim 2, before the deleting an invalid change point in the change point of the data strobe signal, the signal detection method further comprises:
checking correctness of the simulated waveform of the data strobe signal.

7. The signal detection method according to claim 6, wherein the checking correctness of the simulated waveform of the data strobe signal comprises:
obtaining a quantity of correct jumps of the data strobe signal in a data strobe cycle;
calculating a quantity of simulated jumps of the data strobe signal in each data strobe cycle based on the simulated waveform of the data strobe signal; and
comparing the quantity of simulated jumps of the data strobe signal in the data strobe cycle with the quantity of correct jumps, and generating a check result file of the data strobe signal based on a comparison result.

8. The signal detection method according to claim 7, wherein the comparing the quantity of simulated jumps of the data strobe signal in the data strobe cycle with the quantity of correct jumps comprises:
when the quantity of simulated jumps of the data strobe signal in the data strobe cycle is the same as the quantity of correct jumps, determining that the simulated waveform of the data strobe signal in the data strobe cycle is normal; or
when the quantity of simulated jumps of the data strobe signal in the data strobe cycle is different from the quantity of correct jumps, determining that the simulated waveform of the data strobe signal in the data strobe cycle is abnormal.

9. A signal detection method, comprising:
obtaining an excitation file, wherein the excitation file comprises information of a correct output waveform of a to-be-detected signal;
simulating a to-be-detected chip by using a specified emulator, to generate a simulation file, wherein the simulation file comprises information of a simulated waveform of the to-be-detected signal;
comparing the correct output waveform with the simulated waveform to obtain a candidate detection result; and
filtering out a result of a noise point in the candidate detection result to generate a detection result file.

10. The signal detection method according to claim 9, wherein the comparing the correct output waveform with the simulated waveform to obtain a candidate detection result comprises:
sampling the correct output waveform and the simulated waveform under a same sampling condition, and comparing voltage values of the correct output waveform and the simulated waveform at each sampling time point.

11. The signal detection method according to claim 10, wherein the same sampling condition comprises a sampling frequency, the sampling frequency is N times a frequency of a clock signal of the chip, and N is greater than or equal to 2.

12. The signal detection method according to claim 11, wherein the comparing voltage values of the correct output waveform and the simulated waveform at each sampling time point comprises:
when voltage values of the correct output waveform and the simulated waveform at each sampling time point in a half cycle of the clock signal of the chip are not the same, determining that an error occurs on the simulated waveform of the to-be-detected signal in the half cycle of the clock signal of the chip; and
when voltage values of the correct output waveform and the simulated waveform at one or more sampling time points in the half cycle of the clock signal of the chip are the same, determining that no error occurs on the simulated waveform of the to-be-detected signal in the half cycle of the clock signal of the chip.

13. The signal detection method according to claim 12, wherein the filtering out a result of a noise point in the candidate detection result to generate a detection result file comprises:
when a logic voltage value of at least one sampling time point in the half cycle of the clock signal of the chip is the same, determining another target sampling time point with a different logic voltage value in the half cycle as the noise point; and
filtering out a sampling result of the noise point to generate the detection result file.

14. The signal detection method according to claim 9, wherein the to-be-detected signal is an external output signal of the to-be-detected chip.

15. A signal detection apparatus, comprising:
one or more processors; and
a storage apparatus, configured to store one or more programs, wherein the one or more programs, when executed by the one or more processors, cause the one or more processors to execute operations of:
obtaining an excitation file, wherein the excitation file comprises information of a correct output waveform of a to-be-detected signal;
simulating a to-be-detected chip by using a specified emulator, to generate a simulation file, wherein the simulation file comprises information of a simulated waveform of the to-be-detected signal;
filtering out noise in the simulated waveform to obtain a to-be-compared file, wherein the to-be-compared file comprises information of a valid simulated waveform of the to-be-detected signal; and
comparing the to-be-compared file with the excitation file to generate a detection result file.
